(19) United States
(12) Patent Application Publication
(10) Pub. No.: US 2026/0130100 A1
(43) Pub. Date: May 7, 2026

(54) ELECTRONIC DEVICE AND METHOD OF MANUFACTURING THE SAME

(71) Applicant: SAMSUNG DISPLAY CO., LTD., YONGIN-SI (KR)

(72) Inventor: Geun Woo YUG, Yongin-si (KR)

(21) Appl. No.: 19/286,510

(22) Filed: Jul. 31, 2025

(30) Foreign Application Priority Data
Nov. 1, 2024 (KR) 10-2024-0153181
May 9, 2025 (KR) 10-2025-0060565

(51) Int. Cl. H10K 59/80; H10K 59/12; H10K 59/40; H10K 59/65

(52) U.S. Cl. CPC H10K 59/8791; H10K 59/1201; H10K 59/40; H10K 59/65

(57) ABSTRACT

A method of manufacturing an electronic device includes providing a preliminary display device including a display panel and a polarizing plate stacked on the display panel, in which the preliminary display device includes an opening processing area defined by an opening processing line. The method further includes forming an opening line by irradiating the opening processing line with a laser beam. Irradiating the opening processing line with the laser beam begins at an intersection point on the opening processing line. The intersection point is spaced apart, in a laser movement direction, from a crack point at which a virtual vertical line perpendicular to a stretching axis of the polarizing plate and passing through a center of the opening processing area intersects the opening processing line.

### CROSS-REFERENCE TO RELATED APPLICATIONS

This application claims priority under 35 U.S. C. § 119 to Korean Patent Applications No. 10-2024-0153181 filed on Nov. 1, 2024, and 10-2025-0060565 filed on May 9, 2025, the disclosure of which is incorporated by reference herein in its entirety.

### TECHNICAL FIELD

Embodiments of the present disclosure relate to an electronic device and a method of manufacturing the same. More particularly, embodiments of the present disclosure relate to an electronic device including a display panel and a method of manufacturing the same.

### DISCUSSION OF RELATED ART

In a display device such as an organic light-emitting diode (OLED) display device and a liquid display device (LCD), a display substrate including, e.g., a thin film transistor (TFT) and various types of wiring, is provided. A display structure including electrodes and an emission layer may be formed on the display substrate.

Recently, electronic devices in which a sensor, a camera, etc., are combined with a display device to implement a display function are being implemented in the form of, e.g., a smartphone, a monitor, a vehicle screen, etc.

### SUMMARY

According to an aspect of the present disclosure, there is provided an electronic device having improved optical property and mechanical reliability.

According to an aspect of the present disclosure, there is provided a method of manufacturing an electronic device having improved optical property and mechanical reliability.

According to an embodiment of the present disclosure, a method of manufacturing an electronic device includes providing a preliminary display device including a display panel and a polarizing plate stacked on the display panel, in which the preliminary display device includes an opening processing area defined by an opening processing line. The method further includes forming an opening line by irradiating the opening processing line with a laser beam. Irradiating the opening processing line with the laser beam begins at an intersection point on the opening processing line. The intersection point is spaced apart, in a laser movement direction, from a crack point at which a virtual vertical line perpendicular to a stretching axis of the polarizing plate and passing through a center of the opening processing area intersects the opening processing line.

In some embodiments, forming the opening line includes irradiating a first region between a starting point, located adjacent to the intersection point in the opening processing area, and the intersection point with the laser beam to form a cutting start line. The method further includes irradiating the opening processing line with the laser beam from the intersection point along the opening processing line to form an opening formation line. The method further includes irradiating a second region between the intersection point and an end point, located adjacent to the intersection point in the opening processing area, with the laser beam, after the opening formation line reaches the intersection point, to form a cutting end line.

In some embodiments, an angle formed by the intersection point, the center of the opening processing area, and the crack point exceeds about 0° and is less than about 45°.

In some embodiments, the crack point includes a first crack point and a second crack point which face each other with the center of the opening processing area interposed therebetween. The intersection point includes a first intersection point and a second intersection point which are adjacent to the first crack point and the second crack point, respectively. The starting point includes a first starting point and a second starting point which are adjacent to the first intersection point and the second intersection point, respectively. The end point includes a first end point and a second end point which are adjacent to the first intersection point and the second intersection point, respectively.

In some embodiments, the first intersection point and the second intersection point are symmetrical with respect to the center of the opening processing area.

In some embodiments, the opening processing area is divided into a first quadrant, a second quadrant, a third quadrant, and a fourth quadrant from the first crack point along the laser movement direction. The first intersection point is located on a portion of the opening processing line in the first quadrant, and the second intersection point is located on a portion of the opening processing line in the third quadrant.

In some embodiments, the first starting point and the first end point are located in the first quadrant, and the second starting point and the second end point are located in the third quadrant.

In some embodiments, forming the opening line includes performing a first sub-cutting process using the first starting point, the first intersection point, and the first end point, and performing a second sub-cutting process using the second starting point, the second intersection point, and the second end point may be performed.

In some embodiments, the first sub-cutting process and the second sub-cutting process are alternately and repeatedly performed.

In some embodiments, forming the opening line includes forming a tip portion in an area corresponding to the intersection point.

In some embodiments, the method further includes forming an opening by removing portions of the polarizing plate and the display panel cut by the opening line after forming the opening line.

In some embodiments, the method further includes stacking a window substrate on the polarizing plate to cover the opening.

According to an embodiment of the present disclosure, an electronic device includes a display panel, a polarizing plate disposed on the display panel, and an opening penetrating the polarizing plate and the display panel and including a tip portion. The tip portion is spaced apart along an opening line from an intersecting point where a virtual vertical line passing through a center of the opening and perpendicular to a stretching axis of the polarizing plate meets the opening line that defines a circumference of the opening.

In some embodiments, the tip portion has a recessed curved surface in an outward direction of the opening, and a distance between a central point of the opening line included in the tip portion and a peak point of the curved surface is in a range from about 10 μm to about 90 μm.

In some embodiments, an angle between the tip portion, the center of the opening, and the intersecting point exceeds about 0° and is less than about 45°.

In some embodiments, the angle is in a range from about 1° to about 40°.

In some embodiments, the tip portion includes a first tip portion and a second tip portion spaced apart along the opening line.

In some embodiments, the first tip portion and the second tip portion are formed at positions symmetrical to each other with respect to the center of the opening.

In some embodiments, the electronic device further includes a touch sensor layer disposed between the display panel and the polarizing plate. The opening penetrates the polarizing plate, the touch sensor layer, and the display panel.

In some embodiments, the electronic device further includes a functional device inserted into the opening or arranged to overlap the opening. The functional device includes at least one of an optical device, an acoustic element, and a sensor device.

According to embodiments of the present disclosure, a path for forming an opening formed in an electronic device may be set in consideration of a stretching axis of a polarizer.

Accordingly, damage to a periphery of the opening caused by stretching properties of the polarizer may be prevented or reduced, cracks in the opening may be suppressed, and reliability of a functional device inserted into the opening may be maintained for an extended period.

### BRIEF DESCRIPTION OF THE DRAWINGS

The above and other features of the present disclosure will become more apparent by describing in detail embodiments thereof with reference to the accompanying drawings.

FIG. 1 is a schematic exploded perspective view illustrating an electronic device according to embodiments of the present disclosure.

FIG. 2 is a partially enlarged plan view schematically illustrating a structure around an opening of a display device according to embodiments of the present disclosure.

FIG. 3 is a schematic cross-sectional view illustrating a display panel included in an electronic device according to embodiments of the present disclosure.

FIGS. 4 and 5 are schematic cross-sectional views of an electronic device according to embodiments of the present disclosure.

FIGS. 6 to 9 are schematic perspective views illustrating an opening formation mechanism according to embodiments of the present disclosure.

FIG. 10 is a partially enlarged plan view schematically illustrating damage generation occurring in a formation of an opening according to a comparative example.

FIG. 11 is a schematic cross-sectional view illustrating a method of manufacturing an electronic device according to embodiments of the present disclosure.

FIGS. 12 to 18 are partially enlarged plan views schematically illustrating a method of manufacturing an electronic device according to embodiments of the present disclosure.

FIG. 19 is a schematic cross-sectional view illustrating a method of manufacturing an electronic device according to embodiments of the present disclosure.

FIG. 20 is a schematic partially enlarged plan view illustrating an opening shape of an electronic device according to embodiments of the present disclosure.

FIG. 21 is a schematic partially enlarged plan view of a region around an intersection point (tip portion) of an opening formed according to embodiments of the present disclosure.

FIG. 22 is an image of an area including an intersection point (tip portion) of an opening formed according to embodiments of the present disclosure.

FIG. 23 is an image of an area in which an intersection point (tip portion) is not included in an opening formed according to embodiments of the present disclosure.

FIG. 24 is a diagram illustrating an electronic device according to an embodiment of the present disclosure.

### DETAILED DESCRIPTION OF THE EMBODIMENTS

Embodiments of the present disclosure will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below”and “under”can encompass both an orientation of above and below.

It will be understood that when a component is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art, for example, within ±30%, 20%, 10% or 5% of the stated value. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationships between components should be interpreted in a like fashion.

Embodiments of the present disclosure relate to a method of forming an opening in a display panel stack that includes a polarizing plate. For example, embodiments of the present disclosure provide a laser-based cutting method that can address the mechanical and optical vulnerabilities of polarizer materials during opening formation processes. Embodiments may be utilized in electronic devices including precision openings through the display stack, such as for under-display cameras or sensors.

Conventional methods of forming openings in polarizer-integrated display stacks often lead to crack formation, optical defects, or mechanical damage due to the anisotropic nature of the polarizer. For example, when a laser intersects regions aligned with the stretching axis of an iodine-stained PVA polarizing plate, stress concentration can result in cracking or delamination. Such defects can degrade the structural integrity and optical performance of the display, reducing product reliability and manufacturing yield.

Embodiments of the present disclosure address the above by initiating laser processing from an intersection point on an opening processing line that is spaced apart from crack-prone locations. The laser beam may be directed along a carefully controlled path that avoids immediate interaction with stress points related to the polarizer's stretching axis. By delaying the laser's passage through these crack-sensitive regions and subdividing the cutting path into symmetric segments, the method may suppress crack propagation and enable reliable, high-precision opening formation without damaging the polarizer or surrounding layers.

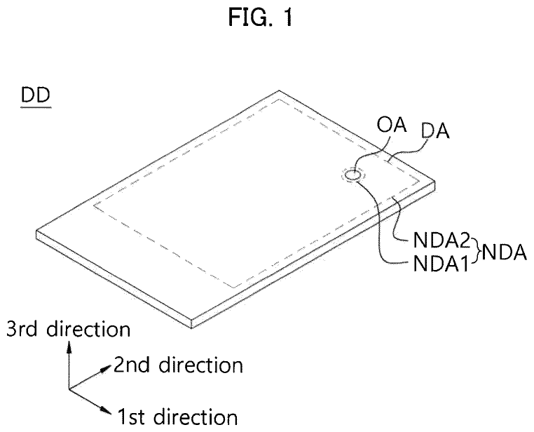

FIG. 1 is a schematic exploded perspective view illustrating an electronic device according to embodiments of the present disclosure. In example embodiments, the electronic device may be implemented in the form of a display device including a screen (display panel) on which an image is displayed. Hereinafter, a display device DD may be described as an implementation example of the electronic device.

In FIG. 1, a first direction and a second direction may refer to two directions that are orthogonal to each other and parallel to the display surface of the display device DD. For example, the first direction may correspond to an X-direction (a row direction), and the second direction may correspond to a Y-direction (a column direction) of the display device DD. The third direction may be perpendicular to the first direction and the second direction. The third direction may correspond to a Z-direction (a thickness direction) of the display device DD.

The above definitions of the directions may be equally applied to all drawings.

Referring to FIG. 1, the display device DD may include a display area DA and a non-display area NDA. The non-display area NDA may include a first non-display area NDA1 and a second non-display area NDA2.

In example embodiments, the display area DA may include a display element such as a light-emitting element capable of emitting light. The light-emitting element may include, for example, an organic light-emitting diode (OLED). The second non-display area NDA2 may include a peripheral portion of the display device DD. In an embodiment, the second non-display area NDA2 may include a light-shielding portion or a bezel portion of the display device.

The display device DD according to embodiments may include an opening OA. The opening OA may have a hole shape formed in the display area DA. The first non-display area NDA1 may be disposed around the opening OA. In an embodiment, the first non-display area NDA1 may have a ring shape surrounding the opening OA.

In some embodiments, the opening OA may be substantially completely surrounded by the first non-display area NDA1. The first non-display area NDA1 may be substantially completely surrounded by the display area DA. For example, the first non-display area NDA1 may form a nearly continuous boundary around the opening OA, such that no portion of the opening OA directly abuts the active display area DA. This configuration may allow for the opening OA to be spatially isolated from pixels or active circuit regions, reducing the risk of, for example, optical artifacts, electrical interference, or mechanical stress at the interface between the opening OA and the display area DA. Similarly, the first non-display area NDA1 may be spatially isolated from surrounding display circuitry by being substantially completely surrounded by the display area DA. In this configuration, the first non-display area NDA1 may be embedded within an interior region of the display panel, with pixel regions disposed on all sides. This arrangement may help maintain uniformity in pixel distribution around the opening OA while preserving a buffer zone that supports signal routing, optical shielding, and structural reinforcement.

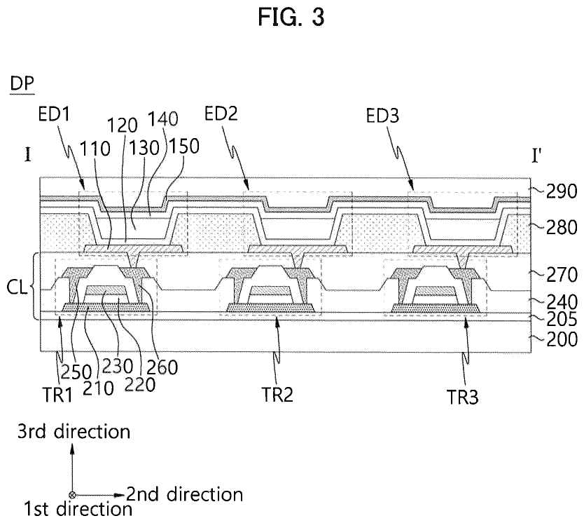

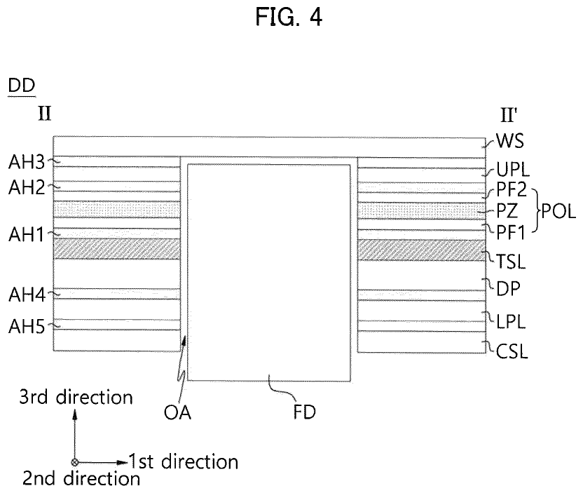

A top surface of the display device DD illustrated in FIG. 1 may correspond to a window substrate WS. For example, a window substrate WS may be stacked on the display panel illustrated in FIG. 3, and the window substrate WS may cover the opening OA (see FIG. 4).

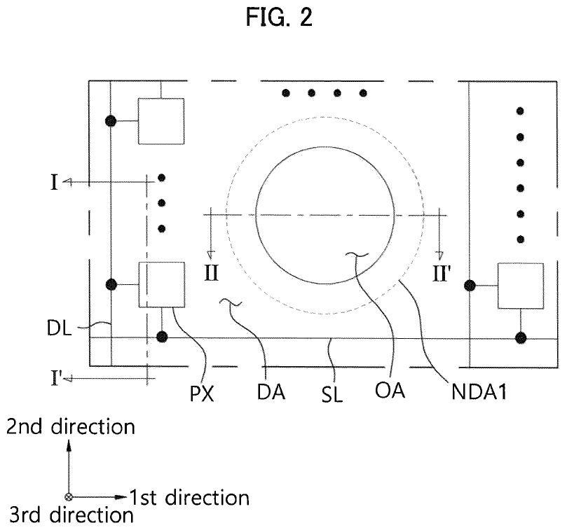

FIG. 2 is a partially enlarged plan view schematically illustrating a structure around an opening of a display device according to embodiments of the present disclosure.

According to embodiments of the present disclosure, a pixel circuit including a plurality of scan lines (or gate lines) SL and a plurality of data lines DL may be arranged on a base substrate 200 (see FIG. 3) of the display device DD. For example, the scan line SL may extend in the first direction, and the data lines DL may extend in the second direction.

Each of the pixels PX may be connected to a corresponding scan line SL among the plurality of the scan lines SL and a corresponding data line DL among the plurality of data lines DL.

Each of the pixels PX may further include a pixel circuit including a transistor and a display element such as, for example, a light-emitting element, as will be described in further detail below. The pixel circuit may further include wirings such as a power line and a ground line.

The pixels PX may be arranged in the display area DA, and are not arranged in the first non-display area NDA1. The first non-display area NDA1 may serve as a buffer area between the opening OA and the display area DA, and may serve as a light-shielding area.

In an embodiment, the scan lines SL and the data lines DL do not extend into the first non-display area NDA1 and the opening OA. For example, the scan lines SL and the data lines DL may be routed around the first non-display area NDA1, such that their paths bypass the region surrounding the opening OA.

In an embodiment, the scan lines SL and the data lines DL may extend along an inner circumference of the first non-display area NDA1, and may bypass the opening OA.

In an embodiment, a peripheral circuit may be disposed in the second non-display area NDA2. For example, the peripheral circuit may include a gate driving circuit. The gate driving circuit may be integrated into the display device DD through, for example, an oxide semiconductor gate (OSG) driver circuit process, an amorphous silicon gate (ASG) driver circuit process, or a polysilicon gate (PSG) driver circuit process. The peripheral circuit may further include, for example, a data driver, a gate driver, a light-emitting driving unit, a power voltage generator, a timing controller, or the like.

Hereinafter, elements/structures of the display device according to embodiments of the present disclosure will be described using an organic light-emitting display device as an example. However, the display device according to embodiments of the present disclosure may be applied to various types of display devices such as, for example, an inorganic light-emitting display device, a quantum dot light-emitting display device, etc.

FIG. 3 is a schematic cross-sectional view illustrating a display panel included in an electronic device according to embodiments of the present disclosure. For example, FIG. 3 is a cross-sectional view taken along line I-I′ of FIG. 2 in the third direction.

Referring to FIG. 3, the display panel DP may include light-emitting elements ED1, ED2, and ED3, and a circuit layer CL electrically connected to the light-emitting elements ED1, ED2, and ED3. The light-emitting elements ED1, ED2, and ED3 and the circuit layer CL may be formed on a base substrate 200.

The base substrate 200 may serve as a supporting substrate or a back-plane substrate of an image display device. A glass substrate or a plastic substrate may be used as the base substrate 200.

In some embodiments, the base substrate 200 may include a polymer material having transparency and flexibility. In this case, the display substrate may be used in a transparent flexible display device. For example, the base substrate 200 may include a polymer material such as polyimide, polysiloxane, an epoxy resin, an acrylic resin, polyester, or the like. In an embodiment, the base substrate 200 may include polyimide.

The circuit layer CL may include transistors TR1, TR2, and TR3. The circuit layer CL may include wiring layers and insulation layers forming a thin film transistor (TFT) array.

The circuit layer CL may further include a buffer layer 205 formed on a top surface of the base substrate 200. Moisture may be blocked by the buffer layer 205 from penetrating through the base substrate 200, and diffusion of impurities between the base substrate 200 and structures formed on the base substrate 200 may be blocked.

The buffer layer 205 may include, e.g., an inorganic insulating material such as silicon oxide, silicon nitride, silicon oxynitride, or the like. These may be used alone or in a combination of two or more therefrom.

In some embodiments, the buffer layer 205 may have a stacked structure including a silicon oxide layer and a silicon nitride layer. The buffer layer 205 may be formed by a deposition process such as, for example, a chemical vapor deposition (CVD) process, a sputtering process, an atomic layer deposition (ALD) process, or the like, to include the above-described inorganic insulating material.

In some embodiments, the buffer layer 205 may include an organic layer, and may have a multi-layered structure of the organic layer and the inorganic layer.

The transistors TR1, TR2, and TR3 may be disposed on the buffer layer 205. A first transistor TR1, a second transistor TR2, and a third transistor TR3 may be electrically connected to the first light-emitting element ED1, the second light-emitting element ED2, and the third light-emitting element ED3, respectively.

Each of the transistors TR1, TR2, and TR3 may include an active layer 210, a gate insulation layer 220, and a gate electrode 230.

The active layer 210 may be disposed on the buffer layer 205, and may be repeatedly/regularly arranged for each pixel. The active layer 210 may include a silicon compound such as polysilicon. A p-type dopant or an n-type dopant may be doped in a partial region of the active layer 210, and the active layer 210 may include a source region, a drain region, and a channel region.

The active layer 210 may include an oxide semiconductor such as, for example, indium gallium zinc oxide (IGZO), zinc tin oxide (ZTO), or indium tin oxide (ITZO).

The gate insulation layer 220 may be formed on the active layer 210, and the gate electrode 230 may be stacked on the gate insulation layer 220. As illustrated in FIG. 3, the gate insulation layer 220 may be formed in a pattern shape partially covering each active layer 210.

In an embodiment, the gate insulation layer 220 may extend continuously over a plurality of pixels or light-emitting regions, and may be commonly included in the first to third transistors TR1, TR2, and TR3.

The gate electrode 230 may overlap the channel region of the active layer 210 in the third direction. A scan signal may be transmitted from a scan line SL through the gate electrode 230.

The gate insulation layer 220 may be formed through the above-described deposition process to include an inorganic insulating material such as, for example, silicon oxide, silicon nitride, silicon oxynitride, or the like. In some embodiments, the gate insulation layer 220 having a patterned shape may be formed as illustrated in FIG. 4 by a photolithography process using the gate electrode 230 as an etching mask.

In some embodiments, the source region and the drain region may be formed in the active layer 210 by using the gate electrode 230 and the gate insulation layer 220 as an ion-implantation mask.

An insulating interlayer 240 covering the gate insulation layer 220 and the gate electrode 230 may be formed on the active layer 210. The connection electrodes 250 and 260 which may be in contact with or electrically connected to the active layer 210 may be disposed on the insulating interlayer 240.

The insulating interlayer 240 may be formed through the above-described deposition process to include an inorganic insulating material such as, for example, silicon oxide, silicon nitride, and silicon oxynitride. The insulating interlayer 240 may be formed in a single-layered structure or a multi-layered structure including different materials.

Connection electrodes 250 and 260 may penetrate the insulating interlayer 240 and may be connected to the active layer 210. When the gate insulation layer 220 is formed continuously and commonly in a plurality of the light-emitting regions, the connection electrodes 250 and 260 may also penetrate the gate insulation layer 220.

The connection electrodes 250 and 260 may include a source electrode 250 that may be connected to or in contact with the source region of the active layer 210, and a drain electrode 260 that may be connected to or in contact with the drain region of the active layer 210.

Contact holes may be formed by partially etching the insulating interlayer 240. For example, contact holes exposing the source region and the drain region, respectively, may be formed. A metal layer filling the contact holes may be formed on the insulating interlayer 240, and then the metal layer may be partially etched to form the source electrode 250 and the drain electrode 260. For example, a data signal may be transferred from a data line through the source electrode 250.

The gate electrode 230 and the connection electrodes 250 and 260 may include a metal such as, e.g., Ag, Mg, Al, W, Cu, Ni, Cr, Mo, Ti, Pt, Ta, Nd, Sc, an alloy thereof, or a nitride thereof. The gate electrode 230 and the connection electrodes 150 and 160 may be formed by the above-described deposition process.

A via insulation layer 270 may be formed on the insulating interlayer 240 to cover the connection electrodes 250 and 260.

The via insulation layer 270 may accommodate a via structure electrically connecting the first electrode 110 and the drain electrode 260. The via insulation layer 270 may serve as a planarization layer of the circuit layer CL. In some embodiments, the via insulation layer 270 may include an organic material such as, for example, polyimide, an epoxy resin, an acrylic resin, polyester, etc. The via insulation layer 270 may be formed by the above-described deposition process or a spin coating process.

The light-emitting elements ED1, ED2, and ED3 may be disposed on the via insulation layer 270. For example, the light-emitting elements ED1, ED2, and ED3 may include the first electrode 110, a hole transfer region 120, an emission layer 130, an electron transfer region 140, and a second electrode 150 sequentially stacked on the via insulation layer 270.

The first electrode 110 may be electrically connected to the transistors TR1, TR2, and TR3 or the connection electrodes 250 and 260 included in the circuit layer CL through the via structure. The first electrode 110 may be in contact with or connected to the drain electrode 260 to serve as a pixel electrode patterned for each light-emitting area or each pixel area.

For example, the via insulation layer 270 may be partially etched to form a via hole exposing a top surface of the drain electrode 260. A conductive layer including a metal material or a transparent conductive oxide and filling the via hole may be formed on a top surface of the via insulation layer 270, and then may be etched to form the first electrode 110.

The first electrode 110 may serve as an anode, and may include a conductive material with a high work function that promotes hole injection. The first electrode 110 may be provided as a transmissive electrode. The first electrode 110 may include a transparent conductive oxide such as, for example, indium tin oxide (ITO), indium zinc oxide (IZO), zinc oxide (ZnO), indium tin oxide (ITZO), etc.

The first electrode 110 may be provided as a translucent electrode or a reflective electrode. The first electrode 110 may include a metal such as, e.g., Ag, Mg, Cu, Al, Pt, Pd, Au, Ni, Nd, Ir, Cr, Li, Ca, LiF, Mo, Ti, W, In, Sn, Zn, or an alloy of two or more therefrom.

The first electrode 110 may have a single-layered structure or a multi-layered structure. For example, the first electrode 110 may have a triple-layered structure of ITO/Ag/ITO.

A pixel defining layer 280 may be formed on the via insulation layer 270 to define the light-emitting region or the pixel region. For example, a red light-emitting region, a green light-emitting region, and a blue light-emitting region may be separated and defined by the pixel defining layer 280, and the light-emitting elements ED1, ED2, and ED3 may correspond to a red light-emitting element, a green light-emitting element, and a blue light-emitting element, respectively. The pixel defining layer 280 may partially cover the first electrode 110 of each light-emitting area.

As illustrated in FIG. 3, the hole transfer region 120 and the electron transfer region 140 may be commonly and continuously formed on the pixel defining layer 280 and a plurality of the first electrodes 110. The emission layer 130 may be formed in the form of an island pattern separated for each light-emitting region or pixel region, and may be defined by the pixel defining layer 280.

In some embodiments, the emission layer 130 may also be commonly and continuously formed over a plurality of the light-emitting regions or pixel regions. In some embodiments, the hole transfer region 120, the emission layer 130, and the electron transfer region 140 may all be separated and selectively formed for each light-emitting region or pixel region.

The emission layer 130 may include an organic light-emitting material independently patterned for each of a red pixel, a green pixel, and a blue pixel to generate different color of lights for each pixel.

For example, the organic light-emitting material may include a host material excited by holes and electrons, and a dopant material that may increase luminous efficiency through absorption and release of energy.

The hole transfer region 120 may include a hole transport layer (HTL) and/or a hole injection layer (HIL). The electron transfer region 140 may include an electron transport layer (ETL) and/or an electron injection layer (EIL).

For example, the hole transfer region 120 may include a hole transport material such as m-MTDATA (4,4′,4″-[tris(3-methylphenyl)phenylamino] triphenylamine), TDATA (4,4′4″-tris(N,N-diphenylamino)triphenylamine), 2-TNATA (4,4′,4″-tris[N(2-naphthyl)-N-phenylamino]-triphenylamine), NPB (N,N′-di(naphthalene-l-yl)-N,N′-diphenyl-benzidine), TPD (N,N′-bis(3-methylphenyl)-N,N′-diphenyl-[1,1′-biphenyl]-4,4′-diamine), TCTA (4,4′,4″-tris(N-carbazolyl)triphenylamine), PEDOT/PSS (poly(3,4-ethylenedioxythiophene)/poly(4-styrenesulfonate)), etc.

For example, the electron transfer region 140 may include an electron transport material such as an anthracene compound, Alq₃ (tris (8-hydroxyquinolinato) aluminum), TPBi (1,3,5-tri(1-phenyl-1H-benzo[d]imidazol-2-yl) benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), etc.

The emission layer 130, the hole transfer region 120, and/or the electron transfer region 140 may be formed by a process such as, for example, thermal deposition, vacuum deposition, spin coating, inkjet printing, laser printing, casting, laser thermal transfer, etc.

The second electrode 150 may serve as a common electrode continuously formed over a plurality of the light-emitting areas or pixel areas. The second electrode 150 may serve as an electron injection electrode or a cathode. The second electrode 150 may include, for example, a metal, an alloy, an electrically conductive compound, or the like, having a low work function.

For example, the second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or the like. These may be used alone or in a combination of two or more therefrom.

The second electrode 150 may be provided as, for example, a transmissive electrode, a translucent electrode, or a reflective electrode. The second electrode 150 may have a single-layered structure or a multi-layered structure.

An encapsulation layer 290 may be disposed on the pixel defining layer 280 and the light-emitting elements ED1, ED2, and ED3 to protect the light-emitting elements ED1, ED2, and ED3 from moisture or oxygen. The encapsulation layer 290 may be formed as a thin film encapsulation (TFE) layer having a single-layered structure or a multi-layered structure.

The encapsulation layer 290 may include, for example, an inorganic layer including silicon nitride (SiNx), silicon oxide (SiOx), indium tin oxide, indium zinc oxide, or any combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE)) or any combination thereof, or a combination of the inorganic layer and the organic layer.

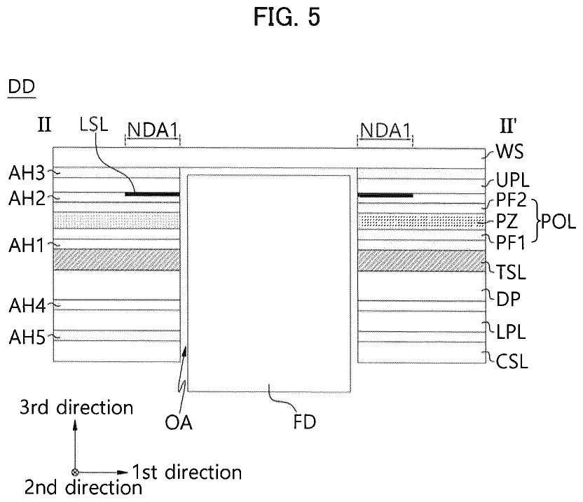

FIGS. 4 and 5 are schematic cross-sectional views of an electronic device according to embodiments of the present disclosure.

Referring to FIG. 4, the display device DD may include a display panel DP described with reference to FIG. 3 and a polarizing plate POL stacked on the display panel DP.

The polarizing plate POL may include a polarizer PZ. A protective film may be attached to a surface of the polarizer PZ to provide a film-type polarizing plate POL.

The polarizer PZ may include an iodine-stained polyvinyl alcohol (PVA) film. The polarizer PZ may be stretched in a specific uniaxial direction to provide a polarization property by an orientation of iodine molecules. The polarizer PZ may have a stretching axis (or an absorption axis) in one direction by iodine molecules oriented in the one direction.

For example, in an embodiment, the polarizer PZ may be formed by staining a PVA film with iodine and then stretching the film in a single direction. This stretching process may align the iodine and polymer molecules along the direction of tension, resulting in the formation of a polarization axis. Light polarized parallel to this axis may be selectively absorbed, while light polarized perpendicular to it is transmitted. As a result, the polarizer PZ may exhibit direction-dependent optical behavior, with the stretching axis also functioning as an absorption axis that defines the polarization characteristics of the film.

The protective film may include a first protective film PF1 attached to a bottom surface of the polarizer PZ and a second protective film PF2 attached to a top surface of the polarizer PZ.

The protective films PF1 and PF2 may include a resin film having improved transparency, mechanical strength, thermal stability, moisture shielding properties, isotropic properties, etc. For example, the protective films PF1 and PF2 may include an acrylic resin film such as polymethyl(meth)acrylate and polyethyl(meth)acrylate, a polyester resin film such as polyethylene terephthalate, polyethylene isophthalate, polyethylene naphthalate and polybutylene terephthalate, a cellulose resin film such as diacetylcellulose and triacetylcellulose, a polyolefin-based resin film such as polyethylene, polypropylene, a cyclo-based or norbonene structure-based resin, and an ethylene-propylene copolymer. In some embodiments, the protective films PF1 and PF2 may include a cellulose-based resin film such as triacetylcellulose (TAC).

In some embodiments, the protective films PF1 and PF2 may be attached to the polarizer PZ by an adhesive layer. For example, the adhesive layer may be formed by coating a photocurable adhesive composition on an attachment surface of the polarizer PZ or the protective films PF1 and PF2, and then crosslinking the adhesive composition by an exposure process. The photocurable adhesive composition may include, for example, an acrylate-based photopolymerizable compound, a photopolymerization initiator, and a solvent.

The term “adhesive layer” as used herein may refer to a pressure sensitive adhesive layer or a bonding layer. The adhesive layer may include an adhesive material such as, for example, an optically clear adhesive (OCA) including an acrylic resin or a silicone resin, an optically clear resin (OCR), etc.

In some embodiments, the polarizing plate POL may further include a quarter wavelength (λ/4) plate. The quarter wavelength plate may be disposed under the polarizer PZ, and may be closer to the display panel DP than the polarizer PZ.

An external light incident through the polarizer PZ may be converted into a circularly polarized light by the quarter wavelength plate, and may be reflected again by the display panel DP to be converted into a reversely rotated circularly polarized light. The reflected external light may pass through the quarter wavelength plate to be converted into a linearly polarized light and absorbed by the polarizer PZ.

For example, in an embodiment, when external ambient light enters the display device DD, it first passes through the polarizer PZ and then through the quarter wavelength plate, which may convert the linearly polarized light into circularly polarized light. This circularly polarized light may then be reflected by the display panel DP and passed back through the quarter wavelength plate, which may convert it into circularly polarized light rotating in the opposite direction. Upon re-entering the polarizer PZ, this now-oppositely polarized light is no longer aligned with the transmission axis and is therefore absorbed by the polarizer PZ. This sequence may reduce reflected glare and improve display contrast under bright external lighting conditions.

A touch sensor layer TSL may be disposed between the display panel DP and the polarizing plate POL. The touch sensor layer TSL may include sensing electrode patterns. The sensing electrode patterns may be included as an on-cell type touch sensor directly deposited and patterned on the encapsulation layer TFE of the display panel DP.

In some embodiments, the touch sensor layer TSL may further include a touch sensor substrate layer in which the sensing electrode patterns are arranged.

The polarizing plate POL may be stacked on the touch sensor layer TSL by a first point adhesive layer AH1.

In some embodiments, an upper protective layer UPL may be disposed on the polarizing plate POL. For example, the upper protective layer UPL may be stacked on the polarizing plate POL by a second adhesive layer AH2 formed on a top surface of the polarizing plate POL.

A lower protective layer LPL may be disposed under a bottom surface of the display panel DP. For example, the lower protective layer LPL may be attached to the display panel DP by a fourth adhesive layer AH4 formed on the bottom surface of the display panel DP.

The upper protective layer UPL and the lower protective layer LPL may suppress damage to the polarizing plate POL and the display panel DP in a laser cutting process as described in further detail below. In some embodiments, the upper protective layer UPL and/or the lower protective layer LPL may be removed after the laser cutting process.

The upper protective layer UPL and the lower protective layer LPL may include a transparent resin film including a polyester resin such as, for example, polyethylene terephthalate (PET), an acrylic resin, an epoxy resin, a urethane resin, an imide resin, a siloxane resin, or the like.

The window substrate WS may be stacked on the upper protective layer UPL or the polarizing plate POL using a third adhesive layer AH3. The window substrate WS may provide an external display surface viewable by a user, such as a visible surface of a mobile phone, a vehicle center fascia, etc., and may include a transparent material film. For example, the window substrate WS may include glass (e.g., ultra-thin glass (UTG)), a hard coating film, a plastic film, or the like.

A cushion layer CSL may be disposed under the display panel DP. In some embodiments, the cushion layer CSL may be attached to the lower protective layer LPL by a fifth point adhesive layer AH5. The cushion layer CSL may absorb impact applied from a rear portion of the display device DD to protect the display panel DP. The cushion layer CSL may include an elastic body such as, for example, a foam.

As described above with reference to FIGS. 1 and 2, the opening OA may extend in the third direction and may penetrate through the display panel DP and the polarizing plate POL. The opening OA may have a hole shape having a substantially circular circumference.

The opening OA may also penetrate the touch sensor layer TSL. The opening OA may also penetrate the upper protective layer UPL and/or the lower protective layer LPL. The opening OA may also penetrate the cushion layer CSL. The window substrate WS may cover the opening OA.

The display device DD/electronic device may include a functional device FD that may be inserted in the opening OA or may overlap the opening OA. The functional device FD may include an optical device such as, for example, a camera, an acoustic device such as a speaker, a sensor device such as a light detection sensor, a thermal detection sensor, or the like.

Referring to FIG. 5, a light-shielding layer LSL may be disposed around the opening OA. The light-shielding layer LSL may substantially surround a periphery of the opening OA in a plan view over the window substrate WS. Accordingly, as illustrated in FIG. 5, the first non-display area NDA1 may be substantially defined by the light-shielding layer LSL.

The light-shielding layer LSL may be a resin layer including a light-shielding color material such as a black color material. For example, the light-shielding layer LSL may include a photosensitive binder resin and the light-shielding color material, and may be selectively formed in the first non-display area NDA1 by a printing process such as, for example, inkjet-printing or a coating process.

In an embodiment, as illustrated in FIG. 5, the light-shielding layer LSL may be formed on a bottom surface of the upper protective layer UPL. In an embodiment, the light-shielding layer LSL may be formed on a bottom surface of the window substrate WS.

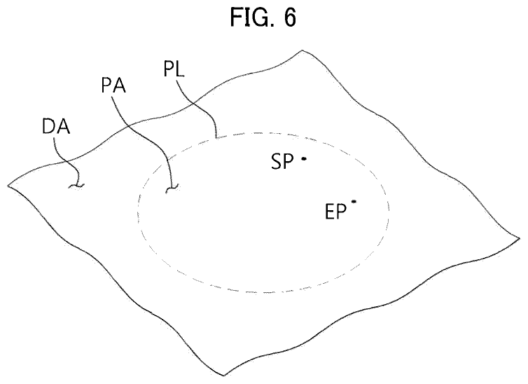

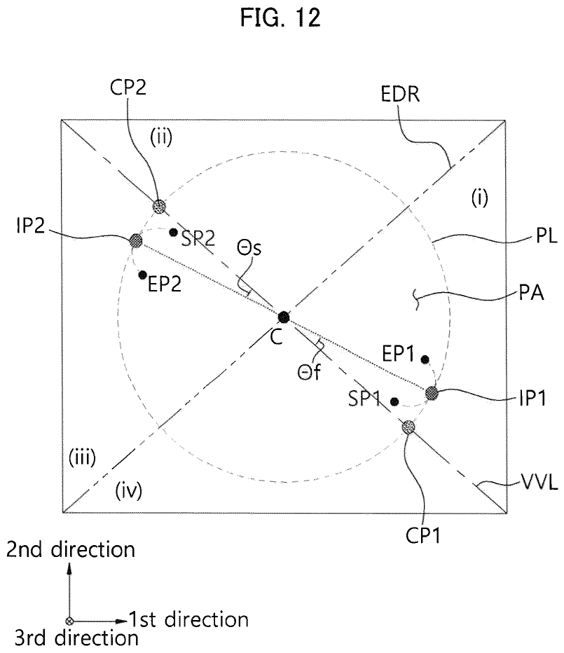

FIGS. 6 to 9 are schematic perspective views illustrating an opening formation mechanism according to embodiments of the present disclosure. For example, FIGS. 6 to 9 are schematic diagrams illustrating a sub-cutting mechanism included in a cutting process described with reference to FIGS. 12 to 18.

Referring to FIG. 6, a laser beam may be irradiated onto a preliminary display device including the display panel DP and the polarizing plate POL before processing an opening by using a laser source LS. In an embodiment, the laser source LS may emit the laser beam and the laser beam may irradiate a surface from beneath the display panel DP (e.g., through the cushion layer CSL or the lower protective layer LPL). In an embodiment, the laser source LS may emit the laser beam to irradiate a surface from above the polarizing plate POL (e.g., through the upper protective layer UPL).

The laser beam may be directed toward a predetermined point disposed within an opening processing area PA, which is formed in the display area DA of the preliminary display device. The opening processing area PA may be defined by an opening processing line PL. The opening processing line PL may be substantially circular.

According to embodiments of the present disclosure, the laser beam emitted from the laser source LS may irradiate the preliminary display device at a starting point SP disposed inside the opening processing area PA.

The opening processing line PL may define a path along which the laser beam emitted from the laser source LS is directed/scanned/moved. Accordingly, the laser beam may be moved along the opening processing line PL and a cutting process or a sub-cutting process may be performed.

In some embodiments, the laser beam provided from the laser source LS may be, for example, a pico-second laser beam or a femto-second laser beam.

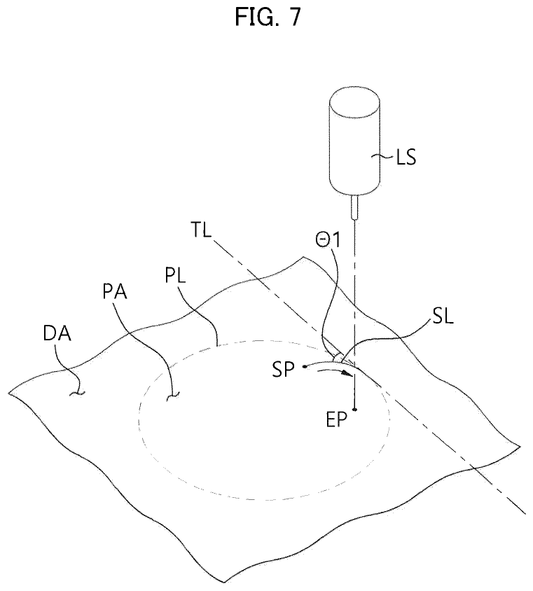

Referring to FIG. 7, the laser beam emitted from the laser source LS may be emitted while being moved in a direction from the starting point SP toward the opening processing line PL. When the laser source LS is operated, the initial laser power in a preheating operation may be less than the laser power immediately before entering the opening processing line PL.

In example embodiments, initial irradiation of the laser beam may be initiated from the starting point SP disposed within the opening processing area PA. Accordingly, the laser beam, having a substantially constant intensity, may be directed along a movement path corresponding to the opening processing line PL, thereby forming the opening.

According to embodiments, the power of the laser beam may range from about 5 W to about 30 W. A laser moving rate at the opening processing line PL may range from about 300 mm/s to about 2000 mm/s. A frequency of the laser beam may range from about 400 KHz to about 2 MHz.

A cutting start line SL may be formed in the opening processing area PA by the above-described laser irradiation initiation. The cutting start line SL may be formed by removing a portion of the preliminary display device as the laser beam provided from the laser source LS is directed along a path from the starting point SP to the opening processing line PL.

The cutting start line SL may have a predetermined first angle θ1 with respect to a tangent line TL at an intersection with the opening processing line PL. The first angle θ1 may be in a range, for example, from about 10° to about 80°, from about 10° to about 70°, from about 15° to about 70°, or from about 20° to about 60°.

In example embodiments, the cutting start line SL may have a curved shape including a predetermined curvature. In an embodiment, the cutting start line SL may have a linear shape. In an embodiment, a length of the cutting start line SL (a length from the starting point SP to the opening processing line PL) may be in a range from about 500 μm to about 750 μm.

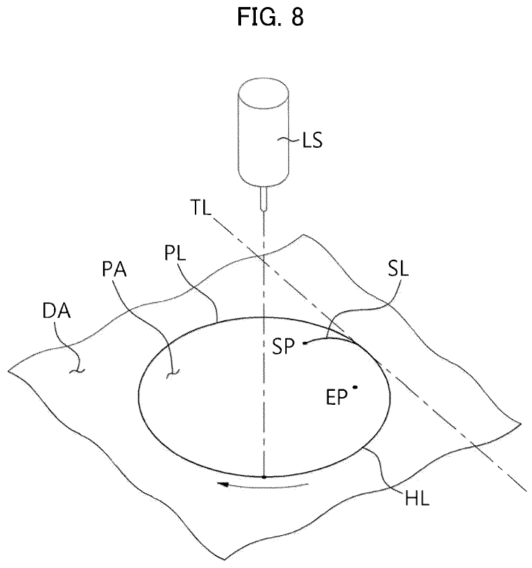

Referring to FIG. 8, as described above, the laser beam may be directed from the starting point SP toward the opening processing line PL, thereby forming the cutting start line SL. The laser beam may be moved along the opening processing line PL, and an opening formation line HL may be formed.

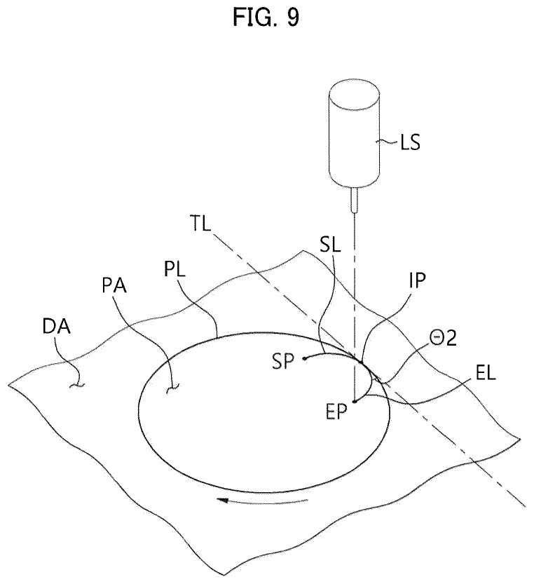

Referring to FIG. 9, the laser source LS may be controlled such that the laser beam is moved from a point along the opening processing line PL to an end point EP disposed within the opening processing area PA. In example embodiments, the laser irradiation may be terminated at the end point EP disposed within the opening processing area PA to maintain a substantially uniform beam intensity along the opening processing line PL (e.g., substantially along the entirety of the opening processing line PL). Thus, the laser beam may be irradiated at a consistent intensity along the opening processing line PL, which may be used to form the final opening.

In example embodiments, a cutting end line EL may be formed in the opening processing area PA. The cutting end line EL may be formed by removing a portion of the preliminary display device as the laser beam is moved from the opening processing line PL to the end point EP.

The cutting end line EL may have a predetermined second angle θ2 with respect to the tangent line TL at an intersection point IP with the opening processing line PL. The second angle θ2 may be in a range, for example, from about 10° to about 80°, about 10° to about 70°, about 15° to about 70°, or from about 20° to about 60°.

In example embodiments, the cutting end line EL may have a curved shape including a predetermined curvature. In an embodiment, the cutting end line EL may have a linear shape. In an embodiment, a length of the cutting end line EL (a length from the end point EP to the opening processing line PL) may be in a range from about 500 μm to about 750 μm.

The cutting start line SL and the cutting end line EL may be divided by an intersection point IP, which may be located on the opening processing line PL. The laser beam emitted from the laser source LS may pass through the intersection point IP twice—once during formation of the cutting start line SL, and again during formation of the cutting end line EL.

Although a moving direction of the laser beam is shown as a clockwise direction in FIG. 7 to FIG. 9, embodiments are not limited thereto. For example, the laser beam may be moved in a counterclockwise direction according to embodiments.

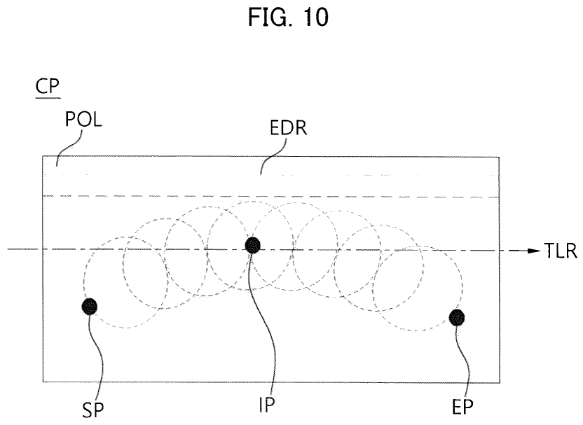

FIG. 10 is a partially enlarged plan view schematically illustrating damage generation occurring during formation of an opening according to a comparative example.

Referring to FIG. 10, the polarizing plate POL or the polarizer PZ may have a stretching direction indicated by a dotted line. As described above, the laser beam may form a laser spot indicated by a dotted circle and may be moved from the start point SP to the end point EP as described above with reference to FIGS. 6 to 9.

An instantaneous movement direction of the laser beam at the intersection point IP may be indicated in a tangential direction TLR.

The iodine molecules included in the polarizing plate POL may be oriented along a stretching direction EDR. As the laser spot indicated by the dotted circle approaches the iodine molecule, heat shrinkage of the polarizer PZ may occur as a sublimation amount of the iodine molecules increases.

In the comparative example as illustrated in FIG. 10, when the tangential direction TLR and the stretching direction EDR, which are the movement directions of the laser spot, are parallel at the intersection point IP of the laser beam, energy of the laser beam may be directly applied to an orientation alignment direction of the iodine molecule, thereby damaging covalent bonds of a polymer chain. Further, sublimated iodine molecules may be externally discharged which may cause bubbles.

Accordingly, a point of the polarizing plate POL or the opening processing line PL corresponding to the intersection point IP may be substantially converted into a crack point CP, causing damage and degradation of reliability of the opening OA.

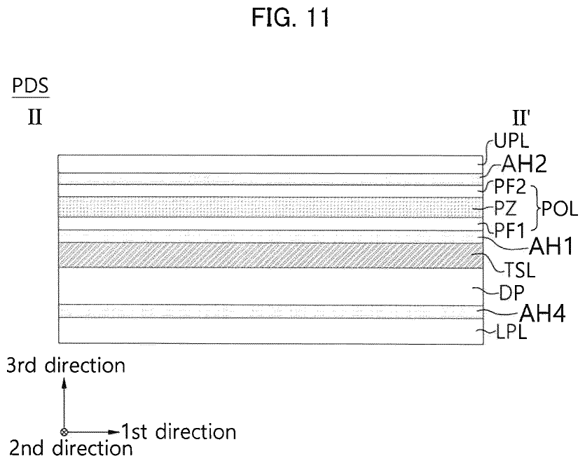

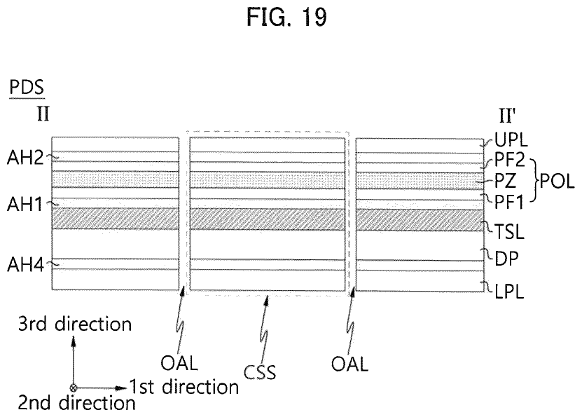

FIG. 11 is a schematic cross-sectional view illustrating a method of manufacturing an electronic device according to embodiments of the present disclosure. FIGS. 12 to 18 are partially enlarged plan views schematically illustrating a method of manufacturing an electronic device according to embodiments of the present disclosure. FIG. 19 is a schematic cross-sectional view illustrating a method of manufacturing an electronic device according to embodiments of the present disclosure. For example, FIGS. 11 and 19 are cross-sectional views taken along line II-II′ of FIG. 2 in the third direction.

For convenience of explanation, a further description of components and technical aspects previously described with reference to FIGS. 1 to 5 are omitted.

Referring to FIG. 11, a preliminary display device PDS may be manufactured or prepared. The preliminary display device PDS may refer to a display device before the opening OA is formed. As described above with reference to FIGS. 4 and 5, the preliminary display device PDS may include the display panel DP and the polarizing plate POL stacked on the display panel DP using the first adhesive layer AH1.

The upper protective layer UPL may be stacked on the polarizing plate POL using the second adhesive layer AH2, and the lower protective layer LPL may be attached to a bottom surface of the display panel DP using the fourth adhesive layer AH4. In an embodiment, the cushion layer CSL (see FIG. 4) may be combined with a bottom surface of the lower protective layer LPL.

A touch sensor layer TSL may be disposed between the polarizing plate POL and the display panel DP.

Referring to FIG. 12, an opening processing line PL, a first crack point CP1, and a second crack point CP2 may be designated to define an opening processing area PA in which the opening is formed.

As described above with reference to FIG. 10, a point in which the stretching direction EDR of the polarizing plate POL and the tangential direction TLR in which the laser spot proceeds is parallel may be designated as the crack point CP at which cracks are caused.

According to embodiments of the present disclosure, two points where a virtual vertical line VVL—passing through a center C of the opening OA or the opening processing area PA and perpendicular to the stretching direction EDR—intersects the opening OA or the opening processing line PL may be designated as a first crack point CP1 and a second crack point CP2.

A first starting point SP1, a first intersection point IP1, and a first end point EP1 may be set based on the first crack point CP1.

According to embodiments of the present disclosure, the first intersection point IP1 may be located on the opening processing line PL, and may be located at a front end in a direction moving along the opening processing line PL of the laser beam or laser source LS (a laser movement direction or a rotation direction) from the first crack point CP1.

For example, according to embodiments, the first intersection point IP1 may lie on the opening processing line PL and may be positioned ahead of the first crack point CP1 along the path of laser movement, such as the scanning or rotational direction of the laser beam emitted from the laser source LS. In this configuration, the laser beam may reach the first crack point CP1 after passing through the intersection point IP1, allowing stress at the crack point to be mitigated by delaying direct exposure during initial cutting.

The term “front end” used herein refers to a point located in front of a specific reference point on the opening processing line PL in a specific rotation direction along the opening processing line PL. For example, according to embodiments of the present disclosure, the specific reference point corresponds to crack points CP1 and CP2, and the specific rotation direction may be a counterclockwise direction.

In some embodiments, a first intersection angle θf formed by the first crack point CP1, the center C, and the first intersection point IP1 may be greater than about 0° and less than about 45°. In an embodiment, the first intersection angle θf may be in a range, for example, from about 1° to about 40°, from about 2° to about 35°, from about 3° to about 30°, or from about 5° to about 15°.

The first starting point SP1 and the first end point EP1 may be set to be adjacent to the first intersection point IP1 in the opening processing area PA.

According to embodiments of the present disclosure, the opening processing area PA may be substantially divided into four quadrants by the stretching axis of the polarizing plate POL extending in the stretching direction EDR and the virtual vertical line VVL. For example, if the rotation direction of the laser source LS is set as a counterclockwise direction, a first quadrant (i), a second quadrant (ii), a third quadrant (iii), and a fourth quadrant (iv) may be defined counterclockwise from the first crack point (CP1).

The first intersection point IP1 may be set at a portion of the opening processing line PL of the first quadrant (i), and the first opening point SP1 and the first end point EP1 may be set in the first quadrant (i).

A second starting point SP2, a second intersection point IP2, and a second end point EP2 may be set based on the second crack point CP2.

According to embodiments of the present disclosure, the second intersection point IP2 may be located on the opening processing line PL, and may be located at a front end in a direction moving along the opening processing line PL (the laser movement direction or the rotation direction) of the laser beam or laser source LS from the second crack point CP2.

In some embodiments, a second intersection angle θf formed by the second crack point CP2, the center C, and the second intersection point IP2 may be greater than about 0° and less than about 45°. In an embodiment, the second intersection angle θf may be in a range, for example, from about 1° to about 40°, from about 2° to about 35°, from about 3° to about 30°, or from about 5° to about 15°.

The second starting point SP2 and the second end point EP2 may be set to be adjacent to the second intersection point IP2 in the opening processing area PA. According to embodiments of the present disclosure, the second intersection point IP2 may be set at a portion of the opening processing line PL of the third quadrant (iii), and the second starting point SP2 and the second end point EP2 may be set in the third quadrant (iii).

In some embodiments, the first intersection point IP1 and the second intersection point IP2 may be substantially symmetrical with respect to the center C. In an embodiment, the first starting point SP1 and the first end point EP1 may be substantially symmetrical to the second starting point SP2 and the second end point EP2, respectively, based on the center C.

In some embodiments, a method of manufacturing the electronic device (e.g., the display device DD) includes providing the preliminary display device PDS including the display panel DP and the polarizing plate POL stacked on the display panel DP, where the preliminary display device PDS includes the opening processing area PA defined by the opening processing line PL. The method further includes forming an opening line OAL (see FIG. 19) by irradiating the opening processing line PL with the laser beam. Irradiating the opening processing line PL with the laser beam includes first irradiating the laser beam onto the first intersection point IP1 on the opening processing line PL. That is, the laser beam is initially emitted onto the first intersection point IP1. As shown in FIG. 12, the first intersection point IP1 is spaced apart, in the laser movement direction (e.g., along the path on which the laser moves), from the first crack point CP1 at which the virtual vertical line VVL perpendicular to the stretching axis of the polarizing plate POL and passing through the center C of the opening processing area PA intersects the opening processing line PL.

In some embodiments, forming the opening line OAL includes irradiating a first region between the first starting point SP1, located adjacent to the first intersection point IP1 in the opening processing area PA, and the first intersection point IP1 with the laser beam to form the cutting start line SL, irradiating the opening processing line PL with the laser beam from the first intersection point IP1 along the opening processing line PL to form an opening formation line HL, and irradiating a second region between the first intersection point IP1 and the first end point EP1, located adjacent to the first intersection point IP1 in the opening processing area PA, with the laser beam, after the opening formation line HL reaches the first intersection point IP1, to form the cutting end line EL.

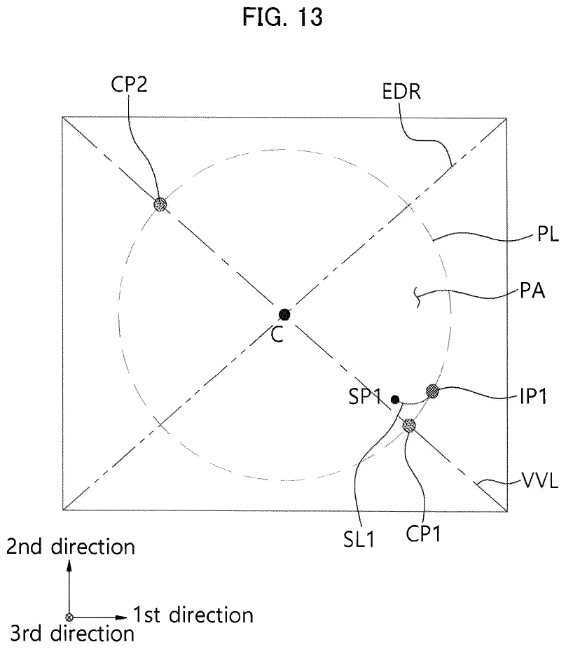

Referring to FIGS. 13 to 15, a first sub-cutting process may be performed using the first starting point SP1, the first intersection point IP1, and the first end point EP1. The first sub-cutting process may be performed in a method substantially the same as or similar to that described above with reference to FIGS. 6 to 9.

As illustrated in FIG. 13, the first sub-cutting process may begin at the first starting point SP1 located within the opening processing area PA. As described with reference to FIGS. 6 to 9, the laser beam may be directed from the first starting point SP1 toward the first intersection point IP1 positioned on the opening processing line PL, thereby forming a first cutting starting line SL1.

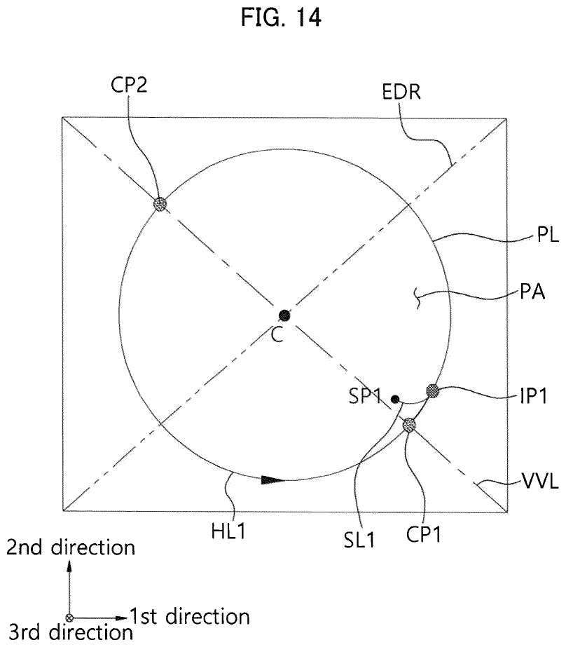

As illustrated in FIG. 14, the laser beam may then be moved along the opening processing line PL starting from the first intersection point IP1. Accordingly, a first opening formation line HL1 may be formed along the opening processing line PL.

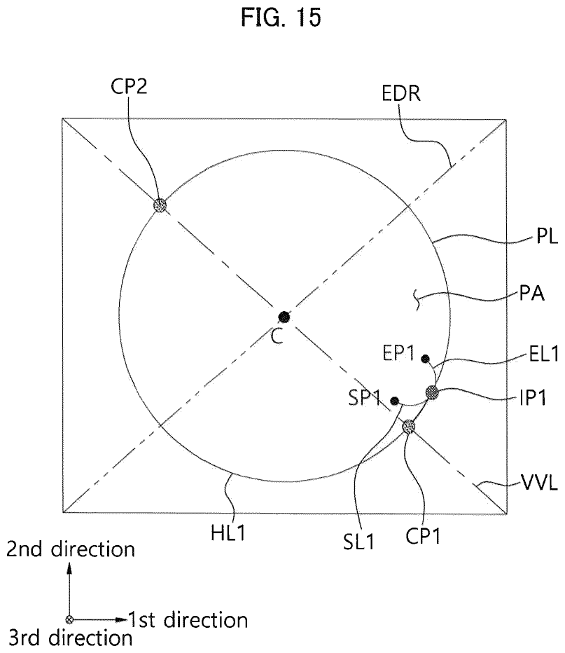

As illustrated in FIG. 15, the laser beam may return to the first intersection point IP1 and then be directed toward the first end point EP1 located within the opening processing area PA, thereby forming a first cutting end line EL1.

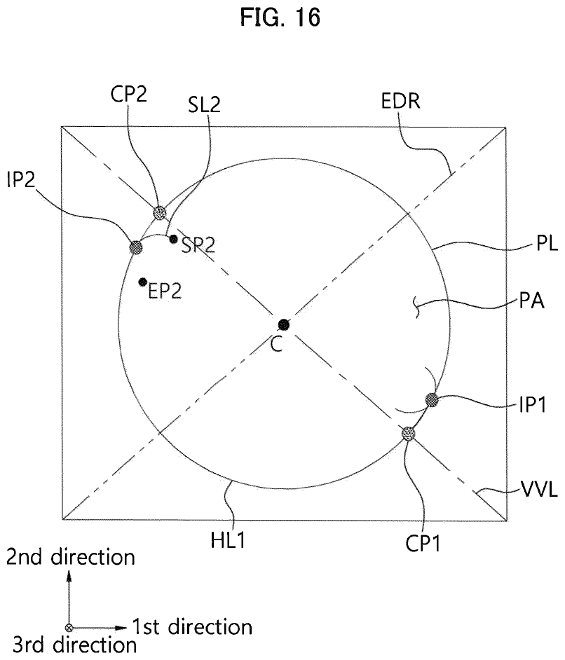

Referring to FIGS. 16 to 18, a second sub-cutting process may be performed by using the second start point SP2, the second intersection point IP2, and the second end point EP2. The second sub-cutting process may be performed using a method substantially the same as or similar to that of the first sub-cutting process.

As illustrated in FIG. 16, the second sub-cutting may begin at the second starting point SP2. As described with reference to FIGS. 6 to 9, the laser beam may be directed from the second starting point SP2 located within the opening processing area PA to the second intersection point IP2 positioned on the opening processing line PL, thereby forming a second cutting starting line SL2.

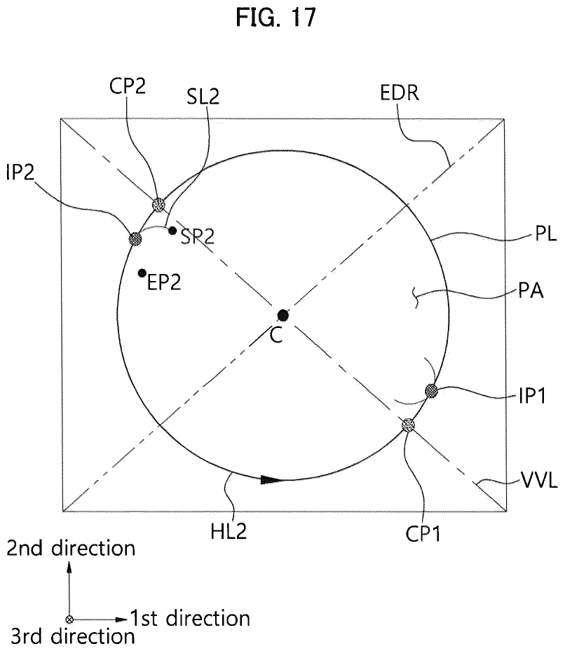

As illustrated in FIG. 17, the laser beam may then be moved along the opening processing line PL starting from the second intersection point IP2. Accordingly, a second opening formation line HL2 may be formed along the opening processing line PL.

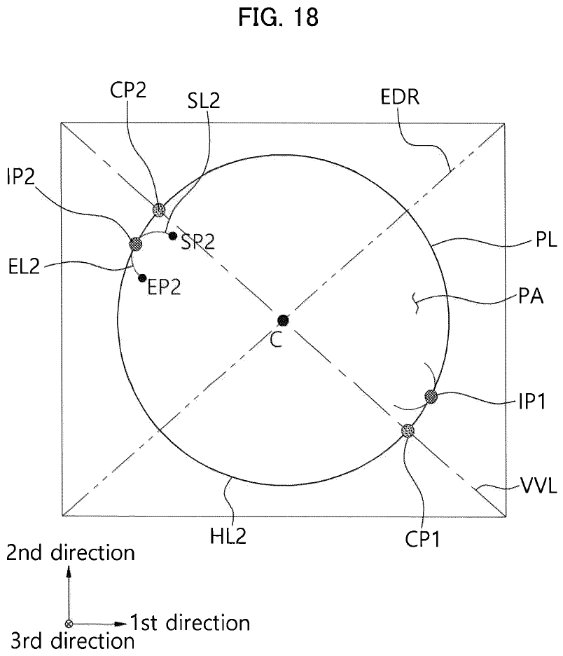

As illustrated in FIG. 18, the laser beam may return to the second intersection point IP2, and then be directed toward the second end point EP2 located within the opening processing area PA, thereby forming a second cutting end line EL2.

Referring to FIG. 19, the above-described first sub-cutting process and second sub-cutting process may be alternately and repeatedly performed. For example, a cutting cycle including the first sub-cutting process and the second sub-cutting process may be repeatedly performed. The number of repetitions of the cutting cycle may be, for example, from about 10 to about 200, from about 10 to about 150, from about 10 to about 100, or from about 50 to about 100.

Accordingly, repeated formation of the first opening formation line HL1 and the second opening formation line HL2 along the opening processing line PL may result in formation of an opening line OAL that penetrates the preliminary display device PDS.

A portion of the preliminary display device PDS surrounded by the opening line OAL may be defined as a cutting stack CSS. The cutting stack CSS may be removed to form the opening OA as illustrated in FIG. 3 or 4.

Thereafter, the window substrate WS may be stacked on the polarizing plate POL or the upper protective layer UPL using the third point adhesive layer AH3 to cover the opening OA.

According to embodiments of the present disclosure described above, the first intersection point IP1 at which the formation of the opening line is substantially initiated may be designated adjacent to the first crack point CP1 in the front end of the rotation direction while avoiding the first crack point CP1. Accordingly, while delaying a time point at which the laser beam passes through the first crack point CP1, the first intersection point IP1 through which the laser beam passes twice may be separated from the first crack point CP1.

For example, according to embodiments, the first intersection point IP1 may be strategically positioned near the first crack point CP1, but slightly forward in the rotation direction of the laser beam along the opening processing line PL. By offsetting the first intersection point IP1 in this manner, the laser beam can begin the cutting process in close proximity to CP1 while intentionally avoiding immediate exposure of the crack-prone region. This configuration may allow the laser beam to approach and pass through the first crack point CP1 after a delay, thereby reducing the risk of damage caused by concentrated thermal or mechanical stress. Furthermore, because the laser beam passes through the first intersection point IP1 twice—once during initiation and again at the conclusion of the cutting path—the positional separation between the first intersection point IP1 and the first crack point CP1 may reduce the likelihood that any stress introduced at the first intersection point IP1 will overlap the mechanically sensitive region at the first crack point CP1.

Additionally, the second intersection point IP2 may be designated to be adjacent to the second crack point CP2 in the front end of the rotation direction while facing the first intersection point IP1 and avoiding the second crack point CP2. Accordingly, while delaying a time point at which the laser beam passes through the second crack point CP2, the second intersection point IP2 through which the laser beam passes twice may be separated from the second crack point CP2.

For example, according to embodiments, the second intersection point IP2 may be positioned adjacent to the second crack point CP2 and slightly forward in the rotation direction of the laser beam, such that it faces the first intersection point IP1 across the center of the opening. Similar to the configuration at the first crack point CP1, this arrangement allows the cutting process to avoid immediate laser exposure at the second crack point CP2 while still initiating and completing a sub-cutting path in its vicinity. By delaying the time at which the laser beam reaches the second crack point CP2, the likelihood of introducing crack-inducing stress at the absorption axis may be reduced. Further, the spatial separation between the second intersection point IP2 and the second crack point CP2 may also limit the possibility that localized stress from the laser beam passing through the second intersection point IP2 twice will coincide with the mechanically sensitive region at the second crack point CP2.

Thus, as described above, according to embodiments of the present disclosure, cracks and bubbles that may otherwise occur at the first and second crack points CP1 and CP2 that may be vulnerable to damages to polymer chains or iodine molecules of the polarizing plate POL may be suppressed.

Further, the first sub-cutting process and the second sub-cutting process may be alternately performed so that a stress application time to the first and second crack points CP1 and CP2 may be alternately delayed. Thus, generation of bubbles and cracks from the first and second crack points CP1 and CP2 may be suppressed.

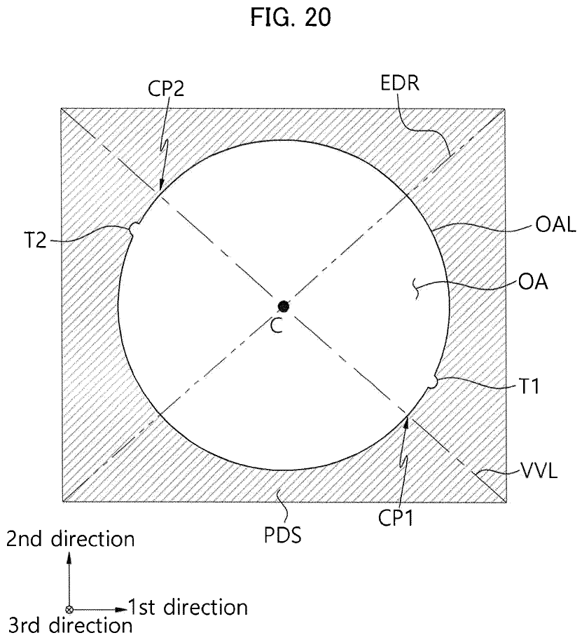

FIG. 20 is a schematic partially enlarged plan view illustrating an opening shape of an electronic device according to embodiments of the present disclosure.

Referring to FIG. 20, as described above, the display device DD or the electronic device may include the opening OA penetrating the preliminary display device PDS including the polarizing plate POL and the display panel DP.

As described above, the laser beam may pass through the first intersection point IP1 twice during the first sub-cutting process, and similarly through the second intersection point IP2 twice during the second sub-cutting process. As a result, the cumulative energy applied at the first intersection point IP1 and the second intersection point IP2 may be relatively greater than at other locations along the opening processing line PL. This increased localized energy input may lead to the formation of tip portions T1 and T2 at the respective positions of the first crack point CP1 and the second crack point CP2, as illustrated in FIG. 20.

The tip portions T1 and T2 may have a protrusion shape protruding from the opening line OAL toward an outside of the opening OA. The tip portions T1 and T2 may include a first tip portion T1 and a second tip portion T2.

The first tip portion T1 may be formed at a position corresponding to the first intersection point IP1 adjacent to the first crack point CP1 that may be one of intersecting points where the virtual vertical line VVL meets the opening line OAL. The second tip portion T2 may be formed at a position corresponding to the second intersection point IP2 adjacent to the second crack point CP2 that may be another of the intersecting points where the virtual vertical line VVL meets the opening line OAL.

In some embodiments, the first tip portion T1 and the second tip portion T2 may be substantially symmetrical with respect to the center C of the opening OA.

In the state in which the opening OA is formed, the tip portions T1 and T2 are adjacent to the crack points CP1 and CP2, and may block or bypass propagation of stress due to an external impact applied to the crack points CP1 and CP2. Thus, mechanical stability and operation reliability of the opening OA and the functional device FD may be more effectively maintained even in the display device in which the opening OA is formed.

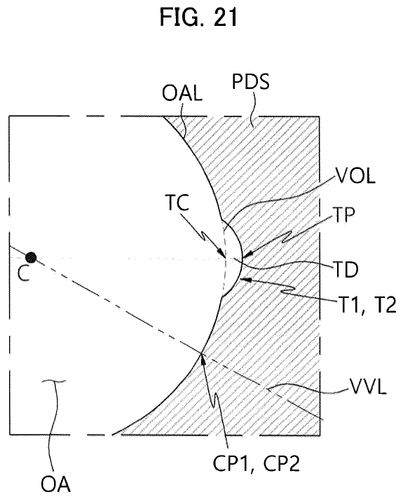

FIG. 21 is a schematic partially enlarged plan view of a region around an intersection point (tip portion) of an opening formed according to embodiments of the present disclosure.

Referring to FIG. 21, as described above, the tip portions T1 and T2 adjacent to the crack points CP1 and CP2 may be formed. The tip portions T1 and T2 may include curved surfaces recessed from the opening line OAL toward the outside of the opening OA. The curved surfaces of the tip portions T1 and T2 may have a peak point TP.

Intersecting points of a virtual extension line VOL from the opening line OAL in an area where the tip portions T1 and T2 are formed and a straight line from the center C of the opening OA toward the peak point TP of the tip portions T1 and T2 may be indicated as a tip center TC. The tip center TC may be a central point of the opening line OAL included in the tip portions T1 and T2.

In some embodiments, a distance TD between the tip center TC and the peak point TP may be in a range from about 10 μm to about 90 μm. In an embodiment, the distance TD between the tip center TC and the peak point TP may be in a range, for example, from about 10 μm to about 80 μm, from about 20 μm to about 80 μm, from about 20 μm to about 70 μm, from about 30 μm to about 70 μm, from about 40 μm to about 80 μm, or from about 40 μm to about 70 μm.

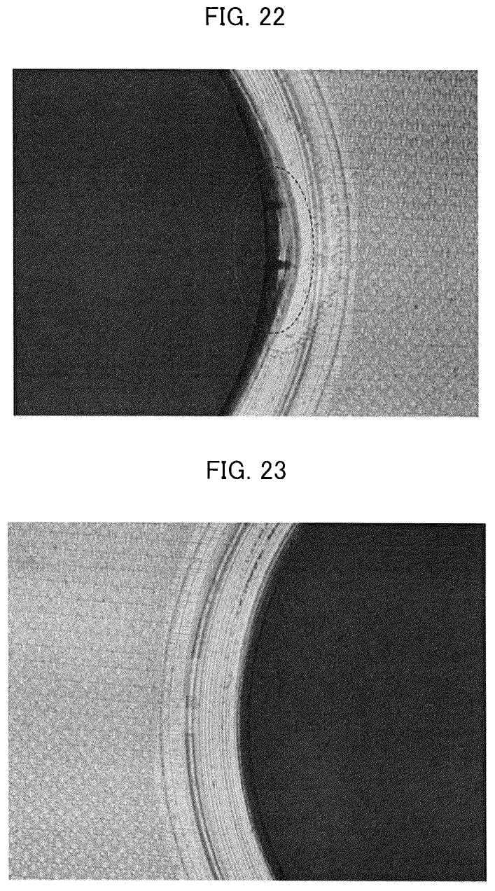

FIG. 22 is an image of an area including an intersection point (tip portion) of an opening formed according to embodiments of the present disclosure. FIG. 23 is an image of an area in which an intersection point (tip portion) is not included in an opening formed according to embodiments of the present disclosure.

Referring to FIG. 22, as described with reference to FIG. 21, the formation of the tip portion having a fine protrusion shape in an outward direction of the opening OA was observed at the intersection points IP1 and IP2 corresponding to an area indicated by a dotted circle of FIG. 22 Referring to FIG. 23, a circumference of the opening OA was formed in a substantially seamless circular shape in an area without the intersection points IP1 and IP2.

The display device/electronic device according to the above-described embodiments may be applied to various electronic devices or products such as a mobile phone, a tablets, a laptop computer, a televisions, a monitor, a digital camera, a camcorder, a portable game console, a vehicle display, a head-up display, a wearable display, an augmented reality or virtual reality display, a billboard, a video wall, etc.

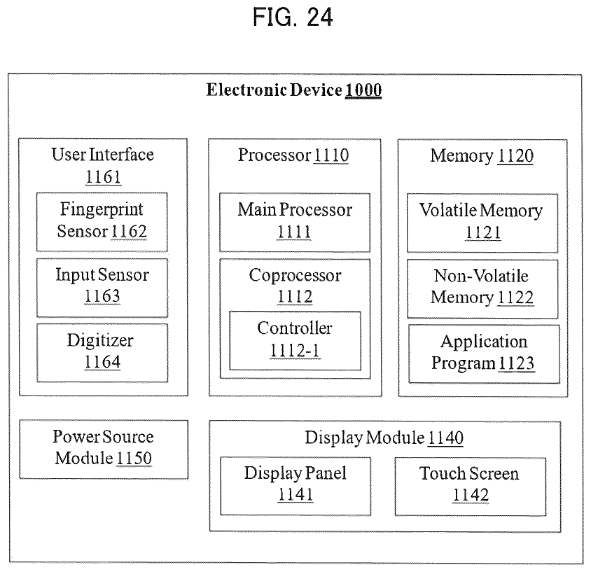

FIG. 24 is a diagram illustrating an electronic device according to an embodiment of the present disclosure.

Referring to FIG. 24, the electronic device 1000 according to an embodiment of the present disclosure may output various information (e.g., images, text, music, etc.) through a display module 1140, which, for example, may correspond to the display device described above. When a processor 1110 executes an application stored in a memory 1120, the display module 1140 may provide application information to a user through a display panel 1141.

In some embodiments, the electronic device 1000 may be configured as a smartphone, camera, smart TV, monitor, smartwatch, tablet, automotive display, or AR/VR headset. For example, the electronic device 1000 may be a smartphone including a touch-sensitive display area DA for interaction and a non-display area NDA including sensors and circuits for enhanced functionality. For example, the electronic device 1000 may be a television or monitor including a large display area DA for high-resolution video playback and a non-display area NDA incorporating driving circuits or connectivity modules for external inputs. For example, the electronic device 1000 may be a smartwatch including a display area DA optimized for compact and high-clarity visuals and a non-display area NDA integrating biometric sensors for health monitoring. In some cases, the electronic device 1000 be an AR/VR headset.

In some embodiments, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device described above.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display unit shown in FIG. 1.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A method of manufacturing an electronic device, comprising:
providing a preliminary display device including a display panel and a polarizing plate stacked on the display panel, wherein the preliminary display device comprises an opening processing area defined by an opening processing line; and
forming an opening line by irradiating the opening processing line with a laser beam,
wherein irradiating the opening processing line with the laser beam begins at an intersection point on the opening processing line,
wherein the intersection point is spaced apart, in a laser movement direction, from a crack point at which a virtual vertical line perpendicular to a stretching axis of the polarizing plate and passing through a center of the opening processing area intersects the opening processing line.

2. The method of claim 1, wherein forming the opening line comprises:
irradiating a first region between a starting point, located adjacent to the intersection point in the opening processing area, and the intersection point with the laser beam to form a cutting start line;
irradiating the opening processing line with the laser beam from the intersection point along the opening processing line to form an opening formation line; and
irradiating a second region between the intersection point and an end point, located adjacent to the intersection point in the opening processing area, with the laser beam, after the opening formation line reaches the intersection point, to form a cutting end line.

3. The method of claim 2, wherein an angle formed by the intersection point, the center of the opening processing area, and the crack point exceeds about 0° and is less than about 45°.

4. The method of claim 2, wherein the crack point includes a first crack point and a second crack point which face each other with the center of the opening processing area interposed therebetween,
the intersection point includes a first intersection point and a second intersection point which are adjacent to the first crack point and the second crack point, respectively,
the starting point includes a first starting point and a second starting point which are adjacent to the first intersection point and the second intersection point, respectively, and
the end point includes a first end point and a second end point which are adjacent to the first intersection point and the second intersection point, respectively.

5. The method of claim 4, wherein the first intersection point and the second intersection point are symmetrical with respect to the center of the opening processing area.

6. The method of claim 4, wherein the opening processing area is divided into a first quadrant, a second quadrant, a third quadrant, and a fourth quadrant from the first crack point along the laser movement direction, and
the first intersection point is located on a portion of the opening processing line in the first quadrant, and the second intersection point is located on a portion of the opening processing line in the third quadrant.

7. The method of claim 6, wherein the first starting point and the first end point are located in the first quadrant, and
the second starting point and the second end point are located in the third quadrant.

8. The method of claim 4, wherein forming the opening line includes performing a first sub-cutting process using the first starting point, the first intersection point, and the first end point, and performing a second sub-cutting process using the second starting point, the second intersection point, and the second end point.

9. The method of claim 8, wherein the first sub-cutting process and the second sub-cutting process are alternately and repeatedly performed.

10. The method of claim 2, wherein forming the opening line includes forming a tip portion in an area corresponding to the intersection point.

11. The method of claim 1, further comprising:
forming an opening by removing portions of the polarizing plate and the display panel cut by the opening line after forming the opening line.

12. The method of claim 11, further comprising:
stacking a window substrate on the polarizing plate to cover the opening.

13. An electronic device, comprising:
a display panel;
a polarizing plate disposed on the display panel; and
an opening penetrating the polarizing plate and the display panel and including a tip portion,
wherein the tip portion is spaced apart along an opening line from an intersecting point where a virtual vertical line passing through a center of the opening and perpendicular to a stretching axis of the polarizing plate meets the opening line that defines a circumference of the opening.

14. The electronic device of claim 13, wherein the tip portion has a recessed curved surface in an outward direction of the opening, and
a distance between a central point of the opening line included in the tip portion and a peak point of the curved surface is in a range from about 10 μm to about 90 μm.

15. The electronic device of claim 13, wherein an angle between the tip portion, the center of the opening, and the intersecting point exceeds about 0° and is less than about 45°.

16. The electronic device of claim 15, wherein the angle is in a range from about 1° to about 40°.

17. The electronic device of claim 13, wherein the tip portion includes a first tip portion and a second tip portion spaced apart along the opening line.

18. The electronic device according to claim 17, wherein the first tip portion and the second tip portion are formed at positions symmetrical to each other with respect to the center of the opening.

19. The electronic device according to claim 13, further comprising:
a touch sensor layer disposed between the display panel and the polarizing plate,
wherein the opening penetrates the polarizing plate, the touch sensor layer, and the display panel.

20. The electronic device according to claim 13, further comprising:
a functional device inserted into the opening or arranged to overlap the opening, wherein the functional device includes at least one of an optical device, an acoustic element, and a sensor device.
